(19) United States
(12) Patent Application Publication
(10) Pub. No.: US 2020/0177126 A1
(43) Pub. Date: Jun. 4, 2020

(54) WIDE TUNING RANGE OSCILLATOR

(71) Applicant: QUALCOMM Incorporated, San Diego, CA (US)

(72) Inventors: Gang LIU, San Diego, CA (US); Mohammad FARAZIAN, San Diego, CA (US); Wu-Hsin CHEN, San Diego, CA (US); Razak HOSSAIN, San Diego, CA (US)

(21) Appl. No.: 16/697,801

(22) Filed: Nov. 27, 2019

Related U.S. Application Data
(60) Provisional application No. 62/772,854, filed on Nov. 29, 2018.

(51) Int. Cl. H03B 5/12

(52) U.S. Cl. CPC H03B 5/1212; H03B 5/124

(57) ABSTRACT

Certain aspects provide a circuit for generating an oscillating signal. The circuit generally includes a voltage-controlled oscillator (VCO) having cross-coupled transistors, a first capacitive element and a second capacitive element coupled to the cross-coupled transistors, and a first inductive element and a second inductive element coupled to the cross-coupled transistors. First terminals of the first inductive element and the second inductive element are coupled to first terminals of the first capacitive element and the second capacitive element, respectively. The circuit also includes a control circuit having an output coupled to a supply voltage node at second terminals of the first inductive element and the second inductive element, and a feedback path coupled between the VCO and an input of the control circuit.

### CLAIM OF PRIORITY

This application claims benefit of U.S. Provisional Patent Application Ser. No. 62/772,854, filed Nov. 29, 2018, which is expressly incorporated herein by reference in its entirety.

### TECHNICAL FIELD

Certain aspects of the present disclosure generally relate to electronic circuits and, more particularly, to circuitry for a voltage-controlled oscillator (VCO).

### BACKGROUND

A wireless communication network may include a number of base stations that can support communication for a number of mobile stations. A mobile station (MS) may communicate with a base station (BS) via a downlink and an uplink. The downlink (or forward link) refers to the communication link from the base station to the mobile station, and the uplink (or reverse link) refers to the communication link from the mobile station to the base station. A base station may transmit data and control information on the downlink to a mobile station and/or may receive data and control information on the uplink from the mobile station. The base station and/or mobile station may include one or more digital-to-analog converters (DACs) for converting digital signals to analog signals.

In some cases, a voltage-controlled oscillator (VCO) may be used to generate a frequency-modulated signal to perform radar operations. For example, the radar operations may be used to detect the presence of a human body in close proximity to a mobile station, based on which the power of signals transmitted by the mobile station may be reduced to comply with regulatory requirements.

### SUMMARY

Certain aspects provide a circuit for generating an oscillating signal. The circuit generally includes a voltage-controlled oscillator (VCO) having cross-coupled transistors, a first capacitive element and a second capacitive element coupled to the cross-coupled transistors, and a first inductive element and a second inductive element coupled to the cross-coupled transistors, first terminals of the first inductive element and the second inductive element being coupled to first terminals of the first capacitive element and the second capacitive element, respectively. The circuit also includes a control circuit having an output coupled to a supply voltage node at second terminals of the first inductive element and the second inductive element, and a feedback path coupled between the VCO and an input of the control circuit.

Certain aspects provide a circuit for generating an oscillating signal. The circuit generally includes a VCO comprising direct-current (DC)-coupled varactors, a control circuit having an output coupled to a supply voltage node of the VCO, and a feedback path coupled between the VCO and an input of the control circuit.

Certain aspects provide a method for generating an oscillating signal. The method generally includes generating the oscillating signal via a VCO having a first varactor and a second varactor, generating a control signal based on a signal at a node of the VCO, the node of the VCO being a tuning node between the first varactor and the second varactor, and controlling a supply voltage of the VCO based on the control signal.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example wireless communications network, in accordance with certain aspects of the present disclosure.

FIG. 2 is a block diagram of an example access point (AP) and example user terminals, in accordance with certain aspects of the present disclosure.

FIG. 3 is a block diagram of an example transceiver front end, in accordance with certain aspects of the present disclosure.

FIG. 4 illustrates a wireless communication system for radar, in accordance with certain aspects of the present disclosure.

FIG. 5 is a block diagram illustrating an example voltage-controlled oscillator (VCO) tuning system, in accordance with certain aspects of the present disclosure.

FIG. 6 is a circuit illustrating example implementations of a VCO and a regulator, in accordance with certain aspects of the present disclosure.

FIG. 7 is a circuit illustrating an example implementation of a VCO with a feedback path from a tuning node of the VCO, in accordance with certain aspects of the present disclosure.

FIG. 8 is a flow diagram illustrating example operations for generating an oscillating signal, in accordance with certain aspects of the present disclosure.

### DETAILED DESCRIPTION

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein, one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### An Example Wireless System

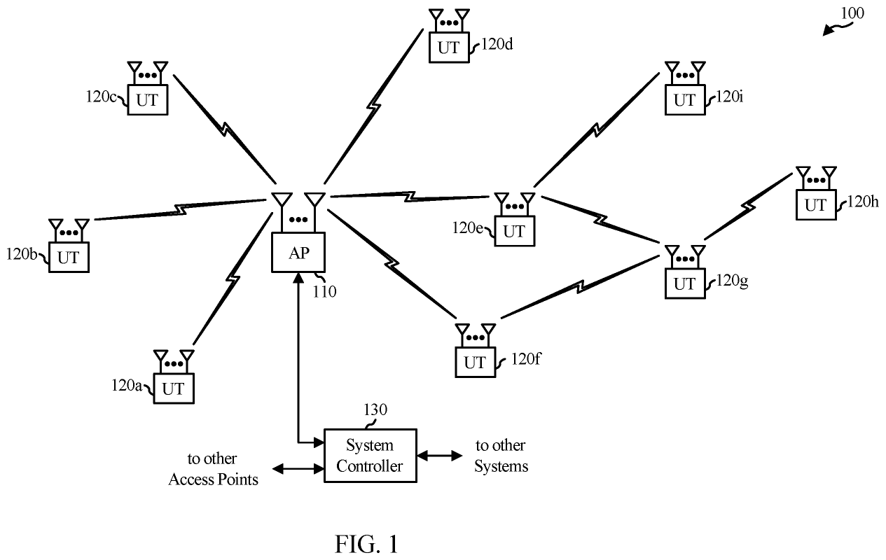

FIG. 1 illustrates a wireless communications system 100 with access points 110 and user terminals 120, in which aspects of the present disclosure may be practiced. For simplicity, only one access point 110 is shown in FIG. 1. An access point (AP) is generally a fixed station that communicates with the user terminals and may also be referred to as a base station (BS), an evolved Node B (eNB), or some other terminology. A user terminal (UT) may be fixed or mobile and may also be referred to as a mobile station (MS), an access terminal, user equipment (UE), a station (STA), a client, a wireless device, or some other terminology. A user terminal may be a wireless device, such as a cellular phone, a personal digital assistant (PDA), a handheld device, a wireless modem, a laptop computer, a tablet, a personal computer, etc.

Access point 110 may communicate with one or more user terminals 120 at any given moment on the downlink and uplink. The downlink (i.e., forward link) is the communication link from the access point to the user terminals, and the uplink (i.e., reverse link) is the communication link from the user terminals to the access point. A user terminal may also communicate peer-to-peer with another user terminal. A system controller 130 couples to and provides coordination and control for the access points.

System 100 employs multiple transmit and multiple receive antennas for data transmission on the downlink and uplink. Access point 110 may be equipped with a number Nₐₚ of antennas to achieve transmit diversity for downlink transmissions and/or receive diversity for uplink transmissions. A set Nᵤ of selected user terminals 120 may receive downlink transmissions and transmit uplink transmissions. Each selected user terminal transmits user-specific data to and/or receives user-specific data from the access point. In general, each selected user terminal may be equipped with one or multiple antennas (i.e., Nᵤₜ≥1). The Nᵤ selected user terminals can have the same or different number of antennas.

Wireless system 100 may be a time division duplex (TDD) system or a frequency division duplex (FDD) system. For a TDD system, the downlink and uplink share the same frequency band. For an FDD system, the downlink and uplink use different frequency bands. System 100 may also utilize a single carrier or multiple carriers for transmission. Each user terminal 120 may be equipped with a single antenna (e.g., to keep costs down) or multiple antennas (e.g., where the additional cost can be supported). In certain aspects of the present disclosure, the access point 110 and/or user terminal 120 may include a voltage-controlled oscillator (VCO), as described in more detail herein.

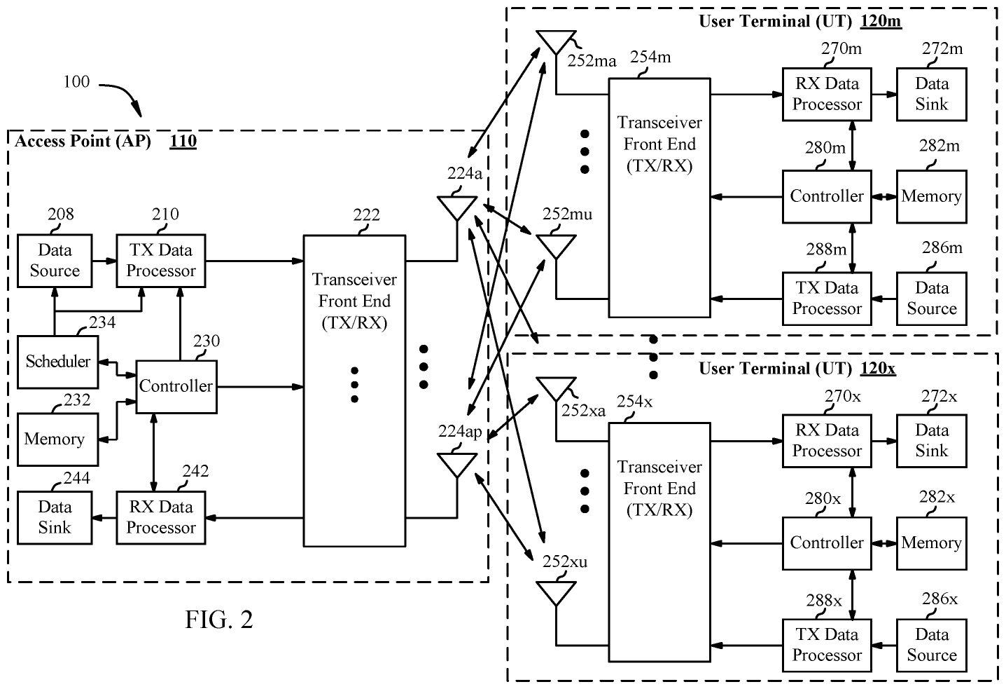

FIG. 2 shows a block diagram of access point 110 and two user terminals 120m and 120x in wireless system 100. Access point 110 is equipped with Nₐₚ antennas 224a through 224ap. User terminal 120m is equipped with N_{ut,m} antennas 252ma through 252mu, and user terminal 120x is equipped with N_{ut,x} antennas 252xa through 252xu. Access point 110 is a transmitting entity for the downlink and a receiving entity for the uplink. Each user terminal 120 is a transmitting entity for the uplink and a receiving entity for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink, Nᵤₚ user terminals are selected for simultaneous transmission on the uplink, N_{dn} user terminals are selected for simultaneous transmission on the downlink, Nᵤₚ may or may not be equal to N_{dn}, and Nᵤₚ and N_{dn} may be static values or can change for each scheduling interval. Beam-steering or some other spatial processing technique may be used at the access point and user terminal.

On the uplink, at each user terminal 120 selected for uplink transmission, a TX data processor 288 receives traffic data from a data source 286 and control data from a controller 280. TX data processor 288 processes (e.g., encodes, interleaves, and modulates) the traffic data {dᵤₚ} for the user terminal based on the coding and modulation schemes associated with the rate selected for the user terminal and provides a data symbol stream {sᵤₚ} for one of the N_{ut,m} antennas. A transceiver front end (TX/RX) 254 (also known as a radio frequency front end (RFFE)) receives and processes (e.g., converts to analog, amplifies, filters, and frequency upconverts) a respective symbol stream to generate an uplink signal. The transceiver front end 254 may also route the uplink signal to one of the N_{ut,m} antennas for transmit diversity via a radio-frequency (RF) switch, for example. The controller 280 may control the routing within the transceiver front end 254. Memory 282 may store data and program codes for the user terminal 120 and may interface with the controller 280.

A number Nᵤₚ of user terminals 120 may be scheduled for simultaneous transmission on the uplink. Each of these user terminals transmits its set of processed symbol streams on the uplink to the access point.

At access point 110, Nₐₚ antennas 224a through 224ap receive the uplink signals from all Nᵤₚ user terminals transmitting on the uplink. For receive diversity, a transceiver front end 222 may select signals received from one of the antennas 224 for processing. The signals received from multiple antennas 224 may be combined for enhanced receive diversity. The access point's transceiver front end 222 also performs processing complementary to that performed by the user terminal's transceiver front end 254 and provides a recovered uplink data symbol stream. The recovered uplink data symbol stream is an estimate of a data symbol stream {sᵤₚ} transmitted by a user terminal. An RX data processor 242 processes (e.g., demodulates, deinterleaves, and decodes) the recovered uplink data symbol stream in accordance with the rate used for that stream to obtain decoded data. The decoded data for each user terminal may be provided to a data sink 244 for storage and/or a controller 230 for further processing. In certain aspects, the transceiver front end (TX/RX) 222 of access point 110 and/or transceiver front end 254 of user terminal 120 may include a VCO, as described in more detail herein.

On the downlink, at access point 110, a TX data processor 210 receives traffic data from a data source 208 for N_{dn} user terminals scheduled for downlink transmission, control data from a controller 230 and possibly other data from a scheduler 234. The various types of data may be sent on different transport channels. TX data processor 210 processes (e.g., encodes, interleaves, and modulates) the traffic data for each user terminal based on the rate selected for that user terminal. TX data processor 210 may provide a downlink data symbol streams for one of more of the N_{dn} user terminals to be transmitted from one of the Nₐₚ antennas. The transceiver front end 222 receives and processes (e.g., converts to analog, amplifies, filters, and frequency upconverts) the symbol stream to generate a downlink signal. The transceiver front end 222 may also route the downlink signal to one or more of the Nₐₚ antennas 224 for transmit diversity via an RF switch, for example. The controller 230 may control the routing within the transceiver front end 222. Memory 232 may store data and program codes for the access point 110 and may interface with the controller 230.

At each user terminal 120, N_{ut,m} antennas 252 receive the downlink signals from access point 110. For receive diversity at the user terminal 120, the transceiver front end 254 may select signals received from one of the antennas 252 for processing. The signals received from multiple antennas 252 may be combined for enhanced receive diversity. The user terminal's transceiver front end 254 also performs processing complementary to that performed by the access point's transceiver front end 222 and provides a recovered downlink data symbol stream. An RX data processor 270 processes (e.g., demodulates, deinterleaves, and decodes) the recovered downlink data symbol stream to obtain decoded data for the user terminal.

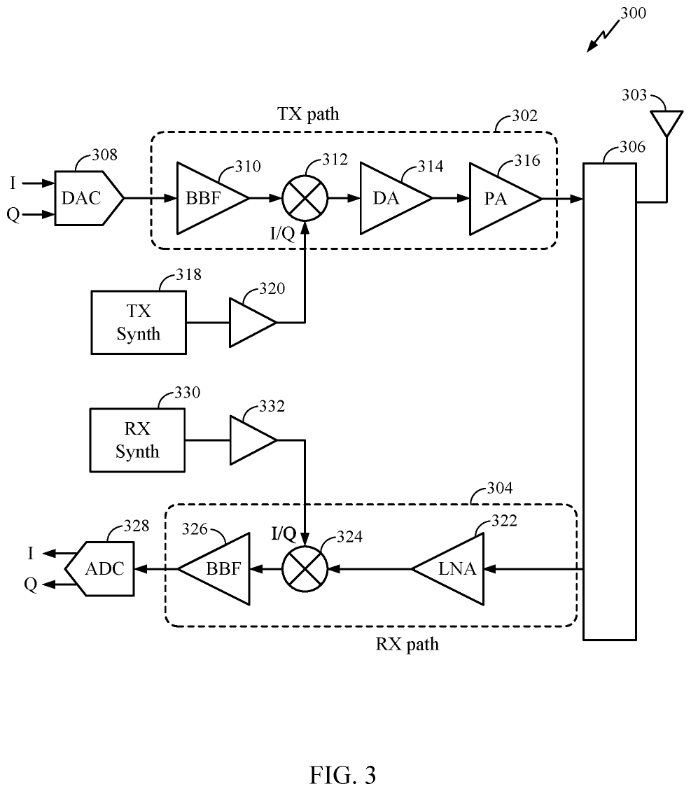

FIG. 3 is a block diagram of an example transceiver front end 300, such as transceiver front ends 222, 254 in FIG. 2, in which aspects of the present disclosure may be practiced. The transceiver front end 300 includes a transmit (TX) path 302 (also known as a transmit chain) for transmitting signals via one or more antennas and a receive (RX) path 304 (also known as a receive chain) for receiving signals via the antennas. When the TX path 302 and the RX path 304 share an antenna 303, the paths may be connected with the antenna via an interface 306, which may include any of various suitable RF devices, such as a duplexer, a switch, a diplexer, and the like.

Receiving in-phase (I) or quadrature (Q) baseband analog signals from a digital-to-analog converter (DAC) 308, the TX path 302 may include a baseband filter (BBF) 310, a mixer 312, a driver amplifier (DA) 314, and a power amplifier (PA) 316. The BBF 310, the mixer 312, and the DA 314 may be included in a radio frequency integrated circuit (RFIC), while the PA 316 may be external to the RFIC. The BBF 310 filters the baseband signals received from the DAC 308, and the mixer 312 mixes the filtered baseband signals with a transmit local oscillator (LO) signal to convert the baseband signal of interest to a different frequency (e.g., upconvert from baseband to RF). This frequency conversion process produces the sum and difference frequencies of the LO frequency and the frequency of the signal of interest. The sum and difference frequencies are referred to as the beat frequencies. The beat frequencies are typically in the RF range, such that the signals output by the mixer 312 are typically RF signals, which may be amplified by the DA 314 and/or by the PA 316 before transmission by the antenna 303.

The RX path 304 includes a low noise amplifier (LNA) 322, a mixer 324, and a baseband filter (BBF) 326. The LNA 322, the mixer 324, and the BBF 326 may be included in a radio frequency integrated circuit (RFIC), which may or may not be the same RFIC that includes the TX path components. RF signals received via the antenna 303 may be amplified by the LNA 322, and the mixer 324 mixes the amplified RF signals with a receive local oscillator (LO) signal to convert the RF signal of interest to a different baseband frequency (i.e., downconvert). The baseband signals output by the mixer 324 may be filtered by the BBF 326 before being converted by an analog-to-digital converter (ADC) 328 to digital I or Q signals for digital signal processing.

While it is desirable for the output of an LO to remain stable in frequency, tuning the LO to different frequencies typically entails using a variable-frequency oscillator, which may involve compromises between stability and tunability. Contemporary systems may employ frequency synthesizers with a voltage-controlled oscillator (VCO) to generate a stable, tunable LO with a particular tuning range. Thus, the transmit LO frequency may be produced by a TX frequency synthesizer 318, which may be buffered or amplified by amplifier 320 before being mixed with the baseband signals in the mixer 312. Similarly, the receive LO frequency may be produced by an RX frequency synthesizer 330, which may be buffered or amplified by amplifier 332 before being mixed with the RF signals in the mixer 324. In certain aspects, the TX frequency synthesizer 318 may include a VCO, as described in more detail herein.

While FIGS. 1-3 provide a wireless communication system as an example application in which certain aspects of the present disclosure may be implemented to facilitate understanding, certain aspects described herein may be used for generating an oscillating signal in any of various other suitable systems.

### Example Wide Tuning Range Oscillator

Fifth generation of wireless systems (5G)/millimeter wave (mmWave) transmission may occur, for example, at 28 GHz or 39 GHz at a power set to achieve a desired throughput at the edge of a cell. A system may transmit a packet of data with a certain desired equivalent isotropically radiated power (EIRP) so that the packet reaches a base station with an acceptable signal-to-noise ratio (SNR). However, if there is a human body within a certain distance of the transmitter, transmitting at the desired EIRP may violate regulations of the Federal Communications Commission (FCC) in the United States and/or other communications governing entity in other countries or regions. Thus, in such a scenario, the transmission power may be reduced. Radar may be used to determine whether a human is within close proximity to the transmitter such that a reduction in transmission power is warranted.

To detect the presence of a human in close proximity, a frequency-modulated continuous wave (FMCW) radar may be used. FMCW radar is implemented by generating a continuous-wave signal transmission, which reflects off of objects (e.g., a human). The reflection is received to detect the object in close proximity to the transmitter. By modulating the frequency of the continuous wave, a distance and speed of an object may also be detected.

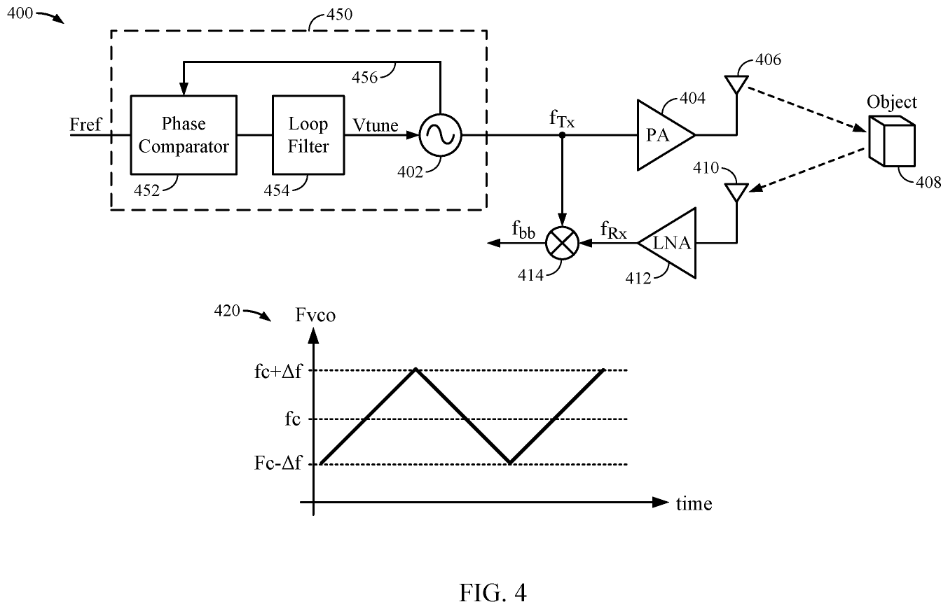

FIG. 4 illustrates a wireless communication system 400 for FMCW radar, in accordance with certain aspects of the present disclosure. The wireless communication system 400 includes a voltage-controlled oscillator (VCO) 402 that generates a transmit signal having a transmit frequency f_{TX}. The VCO 402 may be incorporated in the TX synthesizer 318 described with respect to FIG. 3. For example, the VCO 402 may be part of a phase-locked loop (PLL) 450 having a phase comparator 452, a loop filter 454, and a feedback path 456 from the VCO 402 to the phase comparator 452. In some cases, a charge pump (not shown) may be implemented between the phase comparator 452 and the loop filter 454. The phase comparator 452 may generate a voltage which represents the phase difference between a feedback signal from the VCO 402 and a reference frequency signal (Fref). The voltage generated by the phase comparator 452 is provided to a loop filter 454 (e.g., low-pass filter) to generate a tuning voltage (Vtune) for the VCO 402.

The transmit signal generated by the VCO 402 is amplified via a power amplifier (PA) 404 (e.g., corresponding to PA 316 described with respect to FIG. 3), for transmission via an antenna 406. The signal transmission may reflect off of an object 408, as illustrated. The reflection may be received via an antenna 410, and amplified by a low noise amplifier (LNA) 412. The LNA 412 may correspond to the LNA 322 described with respect to FIG. 3. The LNA 412 generates a receive signal having a receive frequency f_{RX}.

A mixer 414 may be used to mix the transmit signal generated by the VCO 402 and the receive signal generated by the LNA 412 to generate a baseband (BB) signal having a BB frequency f_{bb}. The BB frequency f_{bb} represents the difference between the transmit frequency f_{TX} and receive frequency f_{RX}, which indicates whether the object 408 is in close proximity and a distance of the object 408 from the transmitter. As illustrated by graph 420, the frequency of the VCO (e.g., the transmit frequency f_{TX}) may be modulated to detect the distance of the object 408. For example, the frequency may vary from a center frequency (fc) less a delta frequency (Δf) to the center frequency (fc) plus the delta frequency (Δf). The resolution of the distance detection is related to the bandwidth of the transmit signal generated by the VCO. Thus, a large tuning range may be implemented to detect the distance of the object 408 from the transmitter with a desired resolution.

Certain aspects of the present disclosure provide an inductive-capacitive (LC) VCO implemented with direct-current (DC) coupled varactors to achieve a wide tuning range via continuous analog tuning for a closed-loop FMCW sweep. The DC-coupled varactors enable a wider frequency tuning range as compared to alternating current (AC)-coupled varactors, and allow for automatic adjustment of supply voltage to compensate, or at least adjust, for process, voltage, and temperature (PVT) variations.

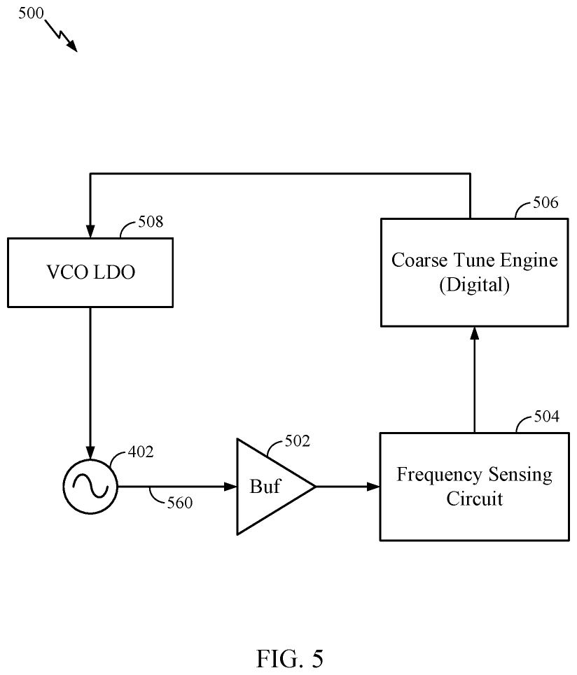

FIG. 5 is a block diagram illustrating an example VCO tuning system 500, in accordance with certain aspects of the present disclosure. As illustrated, the transmit signal generated by the VCO 402 may be buffered via a buffer 502. The transmit frequency f_{TX} of the transmit signal, at the output 560 of the VCO 402, may be sensed via a frequency sensing circuit 504. The frequency sensing circuit 504 provides a signal (e.g., digital signal) representing the transmit frequency f_{TX} to a coarse tuning engine 506. The coarse tuning engine 506 controls a control circuit 508 (e.g., implemented as a low-dropout (LDO) regulator) to tune the VCO 402 based on the sensed transmit frequency f_{TX}. For example, the coarse tuning engine 506 may compare the sensed frequency (e.g., a digital representation thereof) to a target frequency, and control the control circuit 508 accordingly. This closed-loop system provides an automatic adjustment of the VCO frequency to compensate for PVT variations.

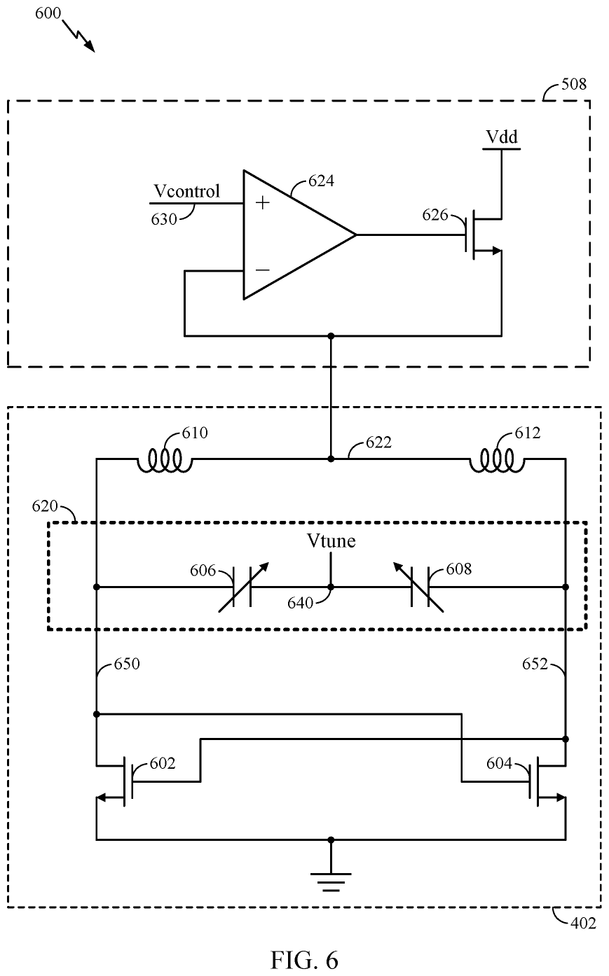

FIG. 6 is a circuit 600 illustrating example implementations of the VCO 402 and control circuit 508 (e.g., LDO regulator), in accordance with certain aspects of the present disclosure. In certain aspects, the VCO 402 is implemented using DC-coupled varactors 620. For example, the VCO 402 includes cross-coupled transistors 602, 604, implementing a negative transconductance circuit that is coupled to varactors 606, 608. That is, a gate of the transistors 602 (e.g., an n-type metal-oxide semiconductor (NMOS) transistor) may be coupled to a drain of the transistor 604 (e.g., an NMOS transistor), and vice versa. The sources of the transistors 602, 604 are coupled to a reference potential node (e.g., electric ground), as illustrated.

The varactors 606, 608 are DC-coupled to inductive elements 610, 612 to form an LC circuit, otherwise referred to as a tank circuit or resonant circuit. The inductive elements 610, 612 may be connected to the supply node 622. The inductive elements 610, 612 may be part of a center-tapped inductive element. The DC-coupled varactors 620 enable a wider frequency tuning range as compared to alternating current (AC)-coupled varactors, as described herein.

In certain aspects, a supply node 622 of the VCO 402, between the inductive elements 610, 612, may be controlled based on feedback from the VCO to compensate, or at least adjust, for PVT variations. For example, a control circuit 508 may generate the supply voltage at the supply node 622 based on a control voltage (Vcontrol) 630 used to coarse tune the VCO. The control circuit 508 may include an amplifier 624 having an output coupled to a gate of a transistor 626. A drain of the transistor 626 may be coupled to a voltage rail Vdd, and the negative input terminal of the amplifier 624 may be coupled to a source of the transistor 626, to generate the supply voltage at supply node 622. That is, the amplifier 624 drives the gate of the transistor 626 to set the supply voltage at the supply node 622 to be about equal to the control voltage 630 at the positive input terminal of the amplifier 624. In certain aspects, the control voltage 630 may be set by the frequency sensing circuit 504 and the coarse tune engine 506, as described with respect to FIG. 5.

The Vtune at the tuning node 640 may be used to adjust the frequency of the oscillating signal generated by the VCO 402 at the output nodes 650, 652 in order to fine tune the VCO. For example, the VCO 402 may be part of the PLL 450 that controls the tuning voltage to lock the frequency and phase of the oscillating signal at the output nodes 650, 652. In other words, Vtune at the tuning node 640 may be controlled via the loop filter 454 to fine tune the VCO as illustrated in FIG. 4, and the control voltage 630 at the positive input terminal of the amplifier 624 may be controlled via the coarse tune engine 506 to coarse tune the VCO.

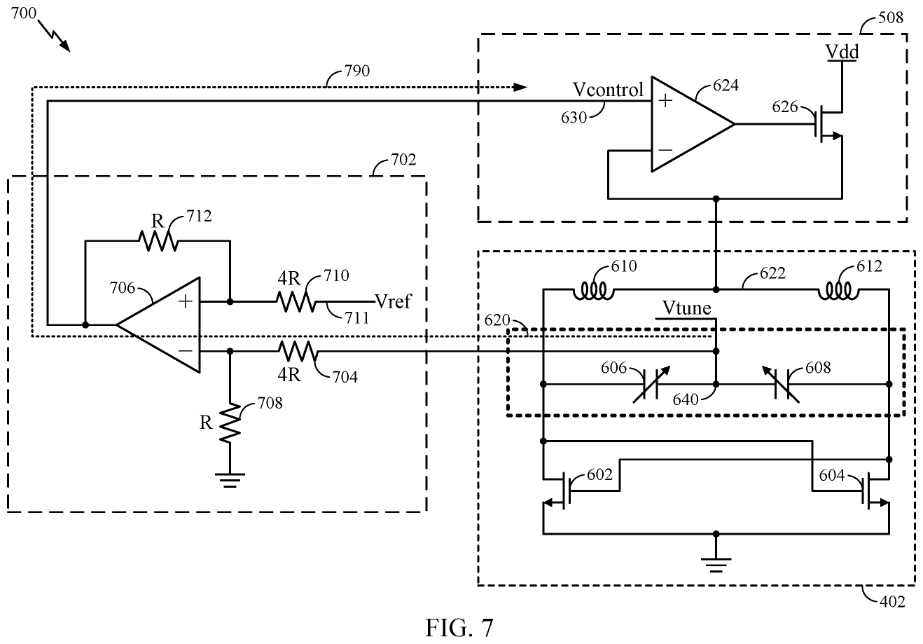

FIG. 7 is a circuit 700 illustrating an example implementation of the VCO 402 with a feedback path 790 from the tuning node 640 of the VCO 402, in accordance with certain aspects of the present disclosure. As illustrated, the feedback path 790 may include a differential amplifier 702 having an input coupled to the tuning node 640, and an output coupled to the positive input terminal of the amplifier 624. For example, the differential amplifier 702 may include a resistive element 704 coupled between the tuning node 640 and the negative input terminal of an amplifier 706, and a resistive element 708 coupled between the negative input terminal of the amplifier 706 and a reference potential node (e.g., electric ground).

The differential amplifier 702 may also include a resistive element 710 coupled to a node 711 for receiving a reference voltage Vref, and a resistive element 712 coupled between the positive input terminal of the amplifier 706 and an output of the amplifier 706 to generate the control voltage Vcontrol at the output of the amplifier 706, as illustrated. In certain aspects, the resistances of the resistive elements 708, 712 may be a quarter of the resistances of the resistive elements 704, 710, such that the control voltage Vcontrol is represented by the following equation:

$$Vcontrol = \frac{Vref - Vtune}{4}$$

Thus, the VCO supply voltage at the supply node 622 changes together with Vtune at the tuning node 640, extending the VCO frequency tuning range. In other words, Vtune at the tuning node 640 may be set by the loop filter 454 to adjust the frequency of the oscillating signal generated by the VCO 402. Vtune may also be fed back to the control circuit 508, via the feedback path 790, to control the VCO supply voltage at the supply node 622. Thus, as Vtune is adjusted via the loop filter 454, the supply voltage at the supply node 622 is also adjusted, extending the VCO frequency tuning range.

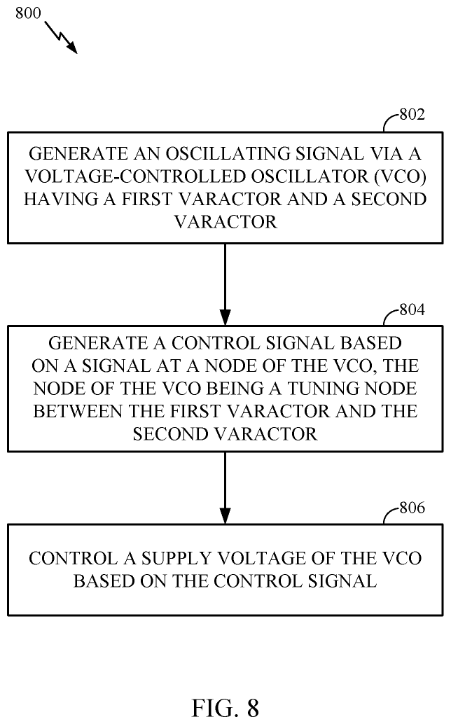

FIG. 8 is a flow diagram illustrating example operations 800 for generating an oscillating signal, in accordance with certain aspects of the present disclosure. The operations 800 may be performed by a circuit, such as the circuit 600 or circuit 700.

The operations 800 begin, at block 802, with the circuit generating the oscillating signal via a VCO (e.g., VCO 402). For example, the VCO may have a first varactor (e.g., varactor 606) and a second varactor (e.g., varactor 608). At block 804, the circuit generates a control signal (e.g., control voltage 630) based on a signal at a node of the VCO. In certain aspects, the node of the VCO may be a tuning node between the first varactor and the second varactor. At block 806, the circuit controls a supply voltage (e.g., at supply node 622) of the VCO based on the control signal.

In certain aspects, the signal at the node of the VCO is the oscillating signal (e.g., at the output 560 of the VCO 402). In this case, the operations 800 also include sensing a frequency of the oscillating signal (e.g., via the frequency sensing circuit 504). The control signal may be generated based on the sensed frequency. In certain aspects, generating the control signal may include comparing the sensed frequency to a target frequency (e.g., via the coarse tune engine 506), and generating the control signal based on the comparison.

In certain aspects, the operations 800 also include adjusting a frequency of the oscillating signal via a tuning voltage (e.g., Vtune). The signal at the node of the VCO, based on which the control signal is generated, may be the tuning voltage.

The various operations of methods described above may be performed by any suitable means capable of performing the corresponding functions. The means may include various hardware component(s) and/or module(s), including, but not limited to one or more circuits. Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The various illustrative logical blocks, modules, and circuits described in connection with the present disclosure may be implemented or performed with discrete hardware components designed to perform the functions described herein.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes and variations may be made in the arrangement, operation and details of the methods and apparatus described above without departing from the scope of the claims.

What is claimed is:

1. A circuit for generating an oscillating signal, comprising:
a voltage-controlled oscillator (VCO) comprising:
cross-coupled transistors;
a first capacitive element and a second capacitive element coupled to the cross-coupled transistors; and
a first inductive element and a second inductive element coupled to the cross-coupled transistors, first terminals of the first inductive element and the second inductive element being coupled to first terminals of the first capacitive element and the second capacitive element, respectively;
a control circuit having an output coupled to a supply voltage node at second terminals of the first inductive element and the second inductive element; and
a feedback path coupled between the VCO and an input of the control circuit.

2. The circuit of claim 1, wherein the feedback path is coupled between an output of the VCO and the input of the control circuit.

3. The circuit of claim 1, wherein the first capacitive element comprises a first varactor direct-current (DC)-coupled to the first inductive element, and wherein the second capacitive element comprises a second varactor DC-coupled to the second inductive element.

4. The circuit of claim 1, wherein second terminals of the first capacitive element and the second capacitive element are coupled to a tuning node of the VCO, the feedback path comprising a differential amplifier coupled between the tuning node and the input of the control circuit.

5. The circuit of claim 1, wherein the cross-coupled transistors comprise a first transistor and a second transistor, wherein a gate of the second transistor is coupled to a drain of the first transistor, and wherein a gate of the first transistor is coupled to a drain of the second transistor.

6. The circuit of claim 5, wherein sources of the first transistor and the second transistor are coupled to a reference potential node.

7. The circuit of claim 1, wherein the control circuit comprises a regulator having:
a transistor; and
an amplifier having an output coupled to a gate of the transistor, wherein a positive input terminal of the amplifier is coupled to the input of the regulator, and wherein a negative input terminal of the amplifier is coupled to the supply voltage node and a source of the transistor.

8. The circuit of claim 1, wherein the feedback path comprises:
a frequency sensing circuit having an input coupled to an output of the VCO and an output coupled to the input of the control circuit.

9. The circuit of claim 1, wherein the first inductive element and the second inductive element are part of a center-tapped inductive element.

10. A circuit for generating an oscillating signal, comprising:
a voltage-controlled oscillator (VCO) comprising direct-current (DC)-coupled varactors;
a control circuit having an output coupled to a supply voltage node of the VCO; and
a feedback path coupled between the VCO and an input of the control circuit.

11. The circuit of claim 10, wherein the feedback path is coupled between an output of the VCO and the input of the control circuit.

12. The circuit of claim 10, wherein the VCO further comprises:
cross-coupled transistors; and
a first inductive element and a second inductive element coupled to the cross-coupled transistors, wherein the DC-coupled varactors comprise a first varactor DC-coupled to the first inductive element and a second varactor DC-coupled to the second inductive element.

13. The circuit of claim 12, wherein the supply voltage node is between the first inductive element and the second inductive element.

14. The circuit of claim 12, wherein a tuning node of the VCO is between the first varactor and the second varactor, the feedback path comprising a differential amplifier coupled between the tuning node and the input of the control circuit.

15. The circuit of claim 12, wherein the cross-coupled transistors comprise a first transistor and a second transistor, wherein a gate of the second transistor is coupled to a drain of the first transistor, and wherein a gate of the first transistor is coupled to a drain of the second transistor.

16. The circuit of claim 15, wherein sources of the first transistor and the second transistor are coupled to a reference potential node.

17. The circuit of claim 10, wherein the control circuit comprises a low-dropout (LDO) regulator.

18. The circuit of claim 17, wherein the LDO regulator comprises:
a transistor; and
an amplifier having an output coupled to a gate of the transistor, wherein a positive input terminal of the amplifier is coupled to an input of the LDO regulator, and wherein a negative terminal of the amplifier is coupled to the supply voltage node and a source of the transistor.

19. The circuit of claim 10, wherein the feedback path comprises:
a frequency sensing circuit having an input coupled to an output of the VCO and an output coupled to the input of the control circuit.

20. A method for generating an oscillating signal, comprising:
generating the oscillating signal via a voltage-controlled oscillator (VCO) having a first varactor and a second varactor;
generating a control signal based on a signal at a node of the VCO, the node of the VCO being a tuning node between the first varactor and the second varactor; and
controlling a supply voltage of the VCO based on the control signal.
